(19) United States
(12) Patent Application Publication
(10) Pub. No.: US 2024/0423097 A1
(43) Pub. Date: Dec. 19, 2024

(54) MAGNETIC MEMORY DEVICES

(71) Applicant: SAMSUNG ELECTRONICS CO., LTD., Suwon-si (KR)

(72) Inventors: JeongMok KIM, Suwon-si (KR); Juhyun KIM, Suwon-si (KR); Se Chung OH, Suwon-si (KR); Junho Jeong, Suwon-si (KR)

(21) Appl. No.: 18/525,322

(22) Filed: Nov. 30, 2023

(30) Foreign Application Priority Data
Jun. 16, 2023 (KR) 10-2023-0077371

(51) Int. Cl. H10N 50/20; H10B 61/00; H10N 50/01; H10N 50/85

(52) U.S. Cl. CPC H10N 50/20; H10B 61/00; H10N 50/01; H10N 50/85

(57) ABSTRACT

A memory device comprising a reference magnetic pattern and a free magnetic pattern sequentially stacked on a substrate; and a tunnel barrier pattern between the reference magnetic pattern and the free magnetic pattern, wherein the reference magnetic pattern includes: a first pinning pattern; a second pinning pattern between the first pinning pattern and the tunnel barrier pattern; and an exchange coupling pattern between the first pinning pattern and the second pinning pattern, the exchange coupling pattern antiferromagnetically coupling the first pinning pattern and the second pinning pattern, wherein the first pinning pattern includes: a first magnetic pattern; and a second magnetic pattern between the first magnetic pattern and the exchange coupling pattern, the first magnetic pattern is a single layer including an alloy of a first ferromagnetic element and a first non-magnetic metal element, and wherein the second magnetic pattern is a single layer including a second ferromagnetic element.

### CROSS-REFERENCE TO RELATED APPLICATION

This U.S. nonprovisional application claims priority under 35 U.S.C §119 to Korean Patent Application No. 10-2023-0077371 filed on Jun. 16, 2023 in the Korean Intellectual Property Office, the disclosure of which is hereby incorporated by reference in its entirety.

### BACKGROUND

The present inventive concepts relate to magnetic memory devices including a magnetic tunnel junction and methods of fabricating the same.

As electronic products trend toward high speed and/or low power consumption, high speed and low operating voltages are increasingly needed for semiconductor memory devices incorporated in the electronic products. In order to meet the demands above, magnetic memory devices have been developed as semiconductor memory devices. Because magnetic memory devices operate at high speeds and have nonvolatile characteristics, they have attracted considerable attention as the next-generation semiconductor memory devices.

In general, the magnetic memory devices may include a magnetic tunnel junction (MTJ) pattern. The magnetic tunnel junction pattern may include two magnetic structures and a dielectric layer interposed therebetween. The resistance of the magnetic tunnel junction pattern may vary depending on magnetization directions of the two magnetic structures. For example, the magnetic tunnel junction pattern may have high (higher) resistance when the magnetization directions of the two magnetic structures are antiparallel and low (lower) resistance when the magnetization directions of the two magnetic structures are parallel. The magnetic memory device may write and read data using the difference between the high and low resistances of the magnetic tunnel junction.

With the remarkable advance in electronic industry, there is an increasing demand for high integration and/or low power consumption of magnetic memory devices, and in addition, many studies have been conducted to improve reliability of magnetic memory devices.

### SUMMARY

Some embodiments of the present inventive concepts provide a magnetic memory device whose reliability is increased and a method of fabricating the same.

According to some embodiments of the present inventive concepts, a memory device may comprise: a reference magnetic pattern and a free magnetic pattern that are sequentially stacked on a substrate; and a tunnel barrier pattern between the reference magnetic pattern and the free magnetic pattern, wherein the reference magnetic pattern includes: a first pinning pattern; a second pinning pattern between the first pinning pattern and the tunnel barrier pattern; and an exchange coupling pattern between the first pinning pattern and the second pinning pattern, the exchange coupling pattern antiferromagnetically coupling the first pinning pattern and the second pinning pattern to each other, wherein the first pinning pattern includes: a first magnetic pattern; and a second magnetic pattern between the first magnetic pattern and the exchange coupling pattern, wherein the first magnetic pattern is a single layer including an alloy of a first ferromagnetic element and a first non-magnetic metal element, and wherein the second magnetic pattern is a single layer including a second ferromagnetic element.

According to some embodiments of the present inventive concepts, a memory device may comprise: a substrate; a lower interlayer dielectric layer on the substrate; a lower wiring line in the lower interlayer dielectric layer; a data storage pattern on the lower wiring line; and a lower contact plug that extends in a first direction between the lower wiring line and the data storage pattern and electrically connects the lower wiring line and the data storage pattern to each other, wherein the first direction is perpendicular to an upper surface of the substrate, wherein the data storage pattern includes: a lower electrode electrically connected to the lower contact plug; and a seed pattern, a reference magnetic pattern, a tunnel barrier pattern, a free magnetic pattern, and an upper electrode that are sequentially stacked on the lower electrode, wherein the reference magnetic pattern includes: a first pinning pattern; a second pinning pattern between the first pinning pattern and the tunnel barrier pattern; and an exchange coupling pattern between the first pinning pattern and the second pinning pattern, the exchange coupling pattern antiferromagnetically coupling the first pinning pattern and the second pinning pattern to each other, wherein the first pinning pattern includes: a first magnetic pattern; and a second magnetic pattern between the first magnetic pattern and the exchange coupling pattern, wherein the first magnetic pattern is a single layer including an alloy of a first ferromagnetic element and a first non-magnetic metal element, and wherein the second magnetic pattern is a single layer including a second ferromagnetic element.

### BRIEF DESCRIPTION OF DRAWINGS

FIG. 1 illustrates a circuit diagram showing a unit memory cell of a magnetic memory device according to some embodiments of the present inventive concepts.

FIG. 2 illustrates a cross-sectional view showing a magnetic memory device according to some embodiments of the present inventive concepts.

FIG. 3 illustrates an enlarged view showing section A of FIG. 2.

FIG. 4 illustrates a plan view showing a magnetic memory device according to some embodiments of the present inventive concepts.

FIG. 5 illustrates a cross-sectional view taken along line I-I′ of FIG. 4.

FIGS. 6 to 11 illustrate cross-sectional views taken along line I-I′ of FIG. 4, showing a method of fabricating a magnetic memory device according to some embodiments of the present inventive concepts.

### DETAILED DESCRIPTION OF EMBODIMENTS

The following will now describe in detail some embodiments of the present inventive concepts with reference to the accompanying drawings.

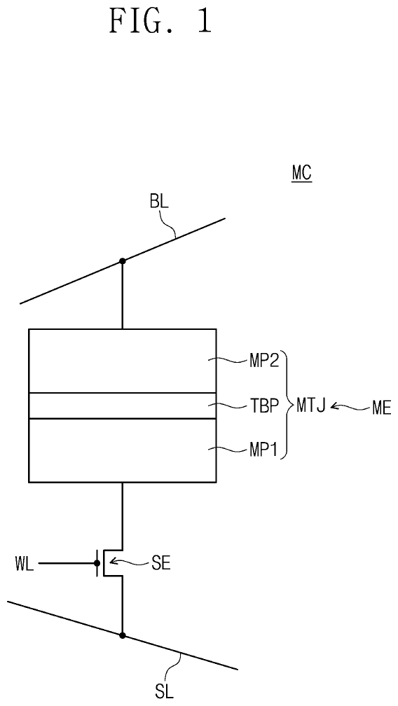

FIG. 1 illustrates a circuit diagram showing a unit memory cell of a magnetic memory device according to some embodiments of the present inventive concepts.

Referring to FIG. 1, a unit memory cell MC may include a memory element ME and a selection element SE. The memory element ME and the selection element SE may be electrically connected to each other in series. The memory element ME may be connected (e.g., electrically connected) between the selection element SE and a bit line BL. The selection element SE may be connected (e.g., electrically connected) between the memory element ME and a source line SL, and may be controlled by a word line WL. The selection element SE may include, for example, a bipolar transistor or a metal oxide semiconductor field effect transistor. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. In addition, it will also be understood that when an element or layer is referred to as being “between” two elements or layers, it may be the only element or layer between the two elements or layers, or one or more intervening elements or layers may also be present.

The memory element ME may include a magnetic tunnel junction pattern MTJ, and the magnetic tunnel junction pattern MTJ may include a first magnetic structure MP1, a second magnetic structure MP2, and a tunnel barrier pattern TBP between the first and second magnetic structures MP1 and MP2. One of the first and second magnetic structures MP1 and MP2 may be a reference magnetic pattern whose magnetization direction is fixed in one direction irrespective of external magnetic field under ordinary use environment. The other of the first and second magnetic structures MP1 and MP2 may be a free magnetic pattern whose magnetization direction is changed due to an external magnetic field between two stable magnetization directions. The magnetic tunnel junction pattern MTJ may have an electrical resistance whose value is much greater in a case that the magnetization directions of the reference and free magnetic patterns are antiparallel to each other than in a case that the magnetization directions of the reference and free magnetic patterns are parallel to each other. For example, the electrical resistance of the magnetic tunnel junction pattern MTJ may be controlled by changing the magnetization direction of the free magnetic pattern. The memory element ME may use the difference in electrical resistance dependent on the magnetization directions of the reference and free magnetic patterns, which mechanism may cause the unit memory cell MC to store data therein.

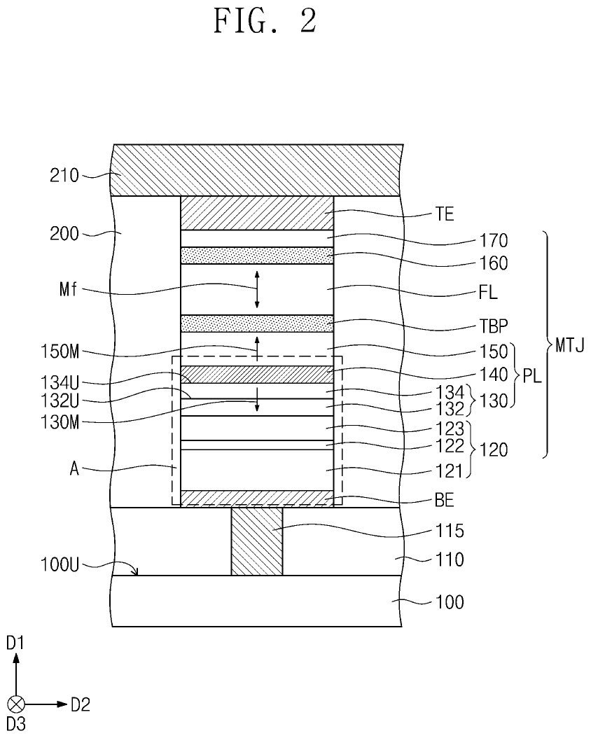

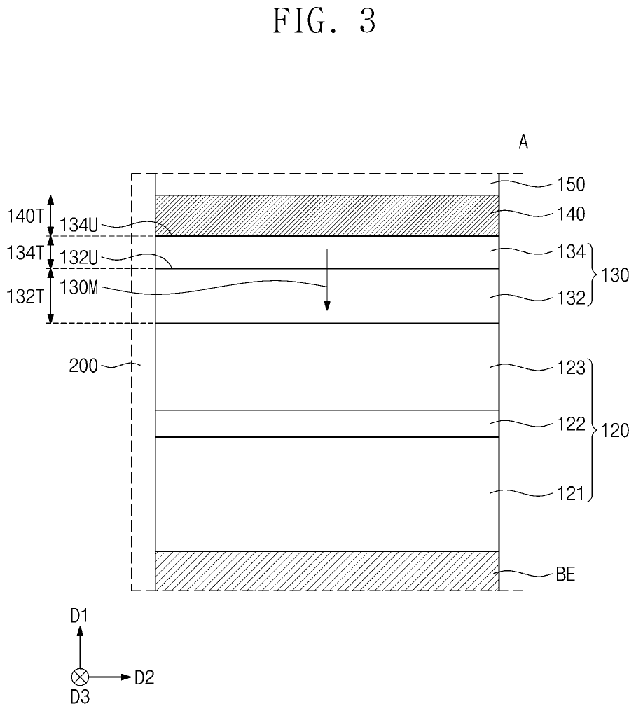

FIG. 2 illustrates a cross-sectional view showing a magnetic memory device according to some embodiments of the present inventive concepts. FIG. 3 illustrates an enlarged view showing section A of FIG. 3.

Referring to FIG. 2, a first interlayer dielectric layer 110 may be disposed on a substrate 100, and a lower contact plug 115 may be disposed in the first interlayer dielectric layer 110. The substrate 100 may be a semiconductor substrate including, for example, silicon (Si), silicon on insulator (SOI), silicon-germanium (SiGe), germanium (Ge), and/or gallium-arsenic (GaAs). The first interlayer dielectric layer 110 may include, for example, silicon oxide, silicon nitride, and/or silicon oxynitride.

The lower contact plug 115 may extend through (e.g., penetrate) the first interlayer dielectric layer 110 and may be electrically connected to the substrate 100. A selection element (see SE of FIG. 1) may be disposed in the substrate 100. The selection element may include, for example, a field effect transistor. The lower contact plug 115 may be electrically connected to one terminal (e.g., a source/drain terminal) of the selection element. The lower contact plug 115 may include, for example, at least one selected from doped semiconductor materials (e.g., doped silicon), metals (e.g., tungsten, titanium, or tantalum), conductive metal nitrides (e.g., titanium nitride, tantalum nitride, or tungsten nitride), and metal-semiconductor compounds (e.g., metal silicide).

A lower electrode BE, a magnetic tunnel junction pattern MTJ, and an upper electrode TE may be sequentially stacked on the lower contact plug 115 along a first direction D1 perpendicular to an upper surface 100U of the substrate 100. The lower electrode BE may be disposed between the lower contact plug 115 and the magnetic tunnel junction pattern MTJ, and the magnetic tunnel junction pattern MTJ may be disposed between the lower electrode BE and the upper electrode TE. The lower electrode BE may be electrically connected to the lower contact plug 115. The lower electrodes BE may include, for example, conductive metal nitride (e.g., titanium nitride or tantalum nitride). The upper electrode TE may include, for example, at least one selected from metal (e.g., Ta, W, Ru, or Ir) and conductive metal nitride (e.g., TiN).

The magnetic tunnel junction pattern MTJ may include a reference magnetic pattern PL, a free magnetic pattern FL, and a tunnel barrier pattern TBP between the reference magnetic pattern PL and the free magnetic pattern FL. According to some embodiments, the reference magnetic pattern PL may be disposed between the lower electrode BE and the tunnel barrier pattern TBP, and the free magnetic pattern FL may be disposed between the upper electrode TE and the tunnel barrier pattern TBP.

The reference magnetic pattern PL may include a first pinning pattern 130, a second pinning pattern 150 between the first pinning pattern 130 and the tunnel barrier pattern TBP, and an exchange coupling pattern 140 between the first pinning pattern 130 and the second pinning pattern 150. The first pinning pattern 130 may include a first magnetic pattern 132 and a second magnetic pattern 134 between the first magnetic pattern 132 and the exchange coupling pattern 140.

The first magnetic pattern 132 may be a single layer including an alloy of a first ferromagnetic element and a non-magnetic metal element. The first ferromagnetic element may include, for example, cobalt (Co), iron (Fe), and/or nickel (Ni), and the non-magnetic metal element may include, for example, platinum (Pt) and/or chromium (Cr). For example, the first magnetic pattern 132 may include at least one selected from FePt, CoPt, NiPt, and CoCrPt. The first magnetic pattern 132 may include a crystal structure of hexagonal close-packed (HCP) lattice. Referring together with FIG. 3, a thickness 132T in the first direction D1 of the first magnetic pattern 132 may range from about 7 angstroms (Å) to about 20 Å (e.g., from 7 Å to 20 Å).

The second magnetic pattern 134 may be a single layer including a second ferromagnetic element. The second ferromagnetic element may include, for example, cobalt (Co) and/or iron (Fe). For example, the second magnetic pattern 134 may be a single layer including one of cobalt (Co), iron (Fe), and CoFe. Referring together with FIG. 3, a thickness 134T in the first direction D1 of the second magnetic pattern 134 may be less than the thickness 132T in the first direction D1 of the first magnetic pattern 132. The thickness 134T in the first direction D1 of the second magnetic pattern 134 may range from about 1 Å to about 5 Å (e.g., from 1 Å to 5 Å), for example, about 3 Å (e.g., 3 Å).

The first pinning pattern 130 may have a first perpendicular magnetization direction 130M perpendicular to an interface between the tunnel barrier pattern TBP and the free magnetic pattern FL. For example, the first perpendicular magnetization direction 130M may be perpendicular to the upper surface 100U of the substrate 100.

The exchange coupling pattern 140 may antiferromagnetically couple the first pinning pattern 130 and the second pinning pattern 150 to each other. The exchange coupling pattern 140 may include a non-magnetic material having antiferromagnetic coupling properties. For example, the exchange coupling pattern 140 may include iridium (Ir) and/or ruthenium (Ru). Referring together with FIG. 3, a thickness 140T in the first direction D1 of the exchange coupling pattern 140 may range from about 3 Å to about 7 Å (e.g., from 3 Å to 7 Å), for example, about 5 Å (e.g., 5 Å).

An upper surface 132U of the first magnetic pattern 132 may be in direct contact with the second magnetic pattern 134, and an upper surface 134U of the second magnetic pattern 134 may be in direct contact with the exchange coupling pattern 140.

The first magnetic pattern 132 may have bulk-perpendicular magnetic anisotropy (bulk-PMA), and the second magnetic pattern 134 may have interface-perpendicular magnetic anisotropy (interface-PMA) that arises at an interface between the second magnetic pattern 134 and the exchange coupling pattern 140. The first perpendicular magnetization direction 130M of the first pinning pattern 130 may originate from the bulk-PMA of the first magnetic pattern 132 and the interface-PMA of the second magnetic pattern 134. For example, the first pinning pattern 130 may have a structure in which a CoPt alloy single layer (as the first magnetic pattern 132) and a cobalt (Co) single layer (as the second magnetic pattern 134) are stacked and in which an Ir layer as the exchange coupling pattern 140 may be stacked on an upper surface of the Co single layer. According to the present inventive concepts, the first perpendicular magnetization direction 130M of the first pinning pattern 130 may originate from bulk-PMA of the CoPt alloy single layer and interface-PMA that arises at an interface between the Co single layer and the Ir layer.

As the bulk-PMA of the first magnetic pattern 132 and the interface-PMA of the second magnetic pattern 134 act at the same time in the first pinning pattern 130, the first pinning pattern 130 may have improved PMA properties and an increased coercive force. The improvement in PMA of the first pinning pattern 130 may induce an improvement in tunnel magnetoresistance (TMR) of the magnetic tunnel junction pattern MTJ. In addition, the increase in coercive force of the first pinning pattern 130 may induce an improvement in retention properties and high-temperature reliability of the magnetic tunnel junction pattern MTJ.

According to the present inventive concepts, a magnetic memory device may be provided in which the magnetic tunnel junction pattern MTJ has improved TMR and retention properties.

The second pinning pattern 150 may include a third ferromagnetic element (e.g., Co and/or Fe), and may further include, for example, molybdenum (Mo), tungsten (W), and/or boron (B). For example, the second pinning pattern 150 may include cobalt (Co), CoFeMo, molybdenum (Mo), tungsten (W), CoFeB, and/or CoFe. The second pinning pattern 150 may be a plurality of layers formed of the third ferromagnetic element. The second pinning pattern 150 may have a layer including a hexagonal close-packed (HCP) lattice or body centered cubic (BCC) crystal structure. The second pinning pattern 150 may have a second perpendicular magnetization direction 150M perpendicular to the interface between the tunnel barrier pattern TBP and the free magnetic pattern FL. For example, the second perpendicular magnetization direction 150M may be perpendicular to the upper surface 100U of the substrate 100. The second pinning pattern 150 may be antiferromagnetically coupled through the exchange coupling pattern 140 to the first pinning pattern 130. Therefore, the second perpendicular magnetization direction 150M may be antiparallel to the first perpendicular magnetization direction 130M of the first pinning pattern 130.

The magnetic tunnel junction pattern MTJ may further include a seed pattern 120 between the lower electrode BE and the reference magnetic pattern PL. At least a portion of the seed pattern 120 may be amorphous. The seed pattern 120 may include a first seed pattern 121, a second seed pattern 122, and a third seed pattern 123 that are sequentially stacked on the lower electrode BE.

The first seed pattern 121 and the second seed pattern 122 may include a non-magnetic metal element. For example, the first seed pattern 121 may include nitride of non-magnetic metal, and the second seed pattern 122 may be a metallic single layer formed of non-magnetic metal. In some embodiments, the second seed pattern 122 may include a non-magnetic metal element the same as that of the first seed pattern 121. For example, the first seed pattern 121 may include tantalum nitride (TaN), and the second seed pattern 122 may include tantalum (Ta). According to some embodiments, a thickness measured in the first direction D1 of the first seed pattern 121 may be greater than a thickness measured in the first direction D1 of the second seed pattern 122. For example, the thickness measured in the first direction D1 of the first seed pattern 121 may be about 50 Å (e.g., 50 Å), and the thickness measured in the first direction D1 of the second seed pattern 122 may be about 10 Å (e.g., 10 Å). The first seed pattern 121 may be (at least partially) amorphous. When Ta of the second seed pattern 122 has a thickness of tens of nanometers (nm) or less, the second seed pattern 122 may grow into beta-phase Ta to become (at least partially) amorphous. As at least portions of the first and second seed patterns 121 and 122 are amorphous, crystallinity of the lower electrode BE disposed thereunder may be prevented from being transferred to the first pinning pattern 130, and thus growth of the first pinning pattern 130 may become easier.

The third seed pattern 123 may include, for example, iridium (Ir) and/or ruthenium (Ru). According to some embodiments, a thickness measured in the first direction D1 of the third seed pattern 123 may range from about 20 Å to about 50 Å (e.g., from 20 Å to 50 Å). The third seed pattern 123 may help C-axis oriented growth of hexagonal close-packed (HCP) lattice to allow the first magnetic pattern 132 to have an HCP lattice.

The tunnel barrier pattern TBP may include, for example, a magnesium (Mg) oxide layer, a titanium (Ti) oxide layer, an aluminum (Al) oxide layer, a magnesium-zinc (MgZn) oxide layer, and/or a magnesium-boron (MgB) oxide layer.

The free magnetic pattern FL may have perpendicular magnetization properties due to magnetic anisotropy induced by junction between the free magnetic pattern FL and the tunnel barrier pattern TBP. A magnetization direction Mf of the free magnetic pattern FL may be changed into parallel or antiparallel to the second perpendicular magnetization direction 150M of the second pinning pattern 150. When the magnetization direction Mf of the free magnetic pattern FL is parallel to the second perpendicular magnetization direction 150M of the second pinning pattern 150, the magnetic tunnel junction pattern MTJ may have a low (a lower) resistance value. In contrast, when the magnetization direction Mf of the free magnetic pattern FL is antiparallel to the second perpendicular magnetization direction 150M of the second pinning pattern 150, the magnetic tunnel junction pattern MTJ may have a high (a higher) resistance value. The free magnetic pattern FL may include a magnetic material capable of inducing magnetic anisotropy at the interface between the free magnetic pattern FL and the tunnel barrier pattern TBP. For example, the free magnetic pattern FL may include cobalt-iron-boron (CoFeB). Hereinafter, the terms, high (higher), low (lower), and the like may refer to relative distances from the substrate 100. For example, element A higher than element B may mean that element A is disposed farther than element B from the upper surface 100U of the substrate 100 in the first direction DI.

The magnetic tunnel junction pattern MTJ may further include a capping pattern 170 between the upper electrode TE and the free magnetic pattern FL, and may also further include an upper non-magnetic pattern 160 between the capping pattern 170 and the free magnetic pattern FL. The upper non-magnetic pattern 160 may include, for example, a magnesium (Mg) oxide layer, a titanium (Ti) oxide layer, an aluminum (Al) oxide layer, a magnesium-zinc (MgZn) oxide layer, and/or a magnesium-boron (MgB) oxide layer. For example, the upper non-magnetic pattern 160 may include the same material as that of the tunnel barrier pattern TBP. The free magnetic pattern FL may have magnetic anisotropy that is improved due to magnetic anisotropy induced at an interface between the upper non-magnetic pattern 160 and the free magnetic pattern FL. The capping pattern 170 may prevent degradation of the free magnetic pattern FL. The capping pattern 170 may include, for example, tantalum (Ta), ruthenium (Ru), molybdenum (Mo), aluminum (Al), copper (Cu), silver (Ag), titanium (Ti), tantalum nitride (TaN), and/or titanium nitride (TiN).

A second interlayer dielectric layer 200 may be disposed on the first interlayer dielectric layer 110, and may cover (at least partially cover) lateral surfaces (side surfaces) of the lower electrode BE, the magnetic tunnel junction pattern MTJ, and the upper electrode TE. The second interlayer dielectric layer 200 may include, for example, silicon oxide, silicon nitride, and/or silicon oxynitride.

The second interlayer dielectric layer 200 may be provided thereon with an upper wiring line 210 connected (e.g., electrically connected) to the upper electrode TE. The upper wiring line 210 may extend in a second direction D2 parallel to the upper surface 100U of the substrate 100. The upper wiring line 210 may be connected (e.g., electrically connected) through the upper electrode TE to the magnetic tunnel junction pattern MTJ, and may serve as the bit line BL of FIG. 1. The upper wiring line 210 may include at least one selected from metal (e.g., copper) and conductive metal nitride.

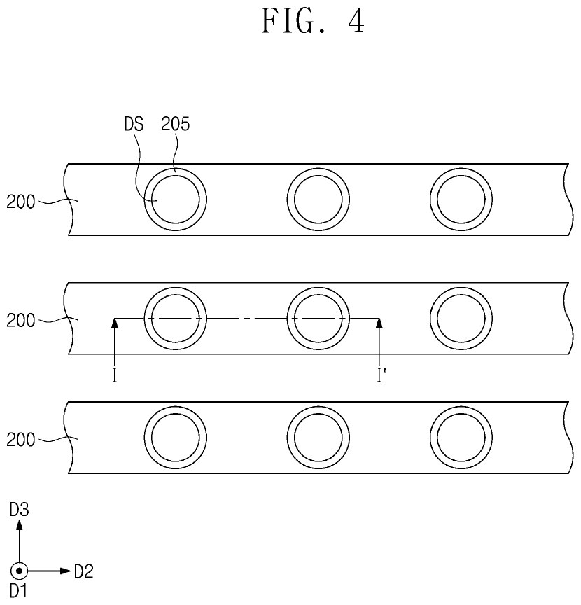

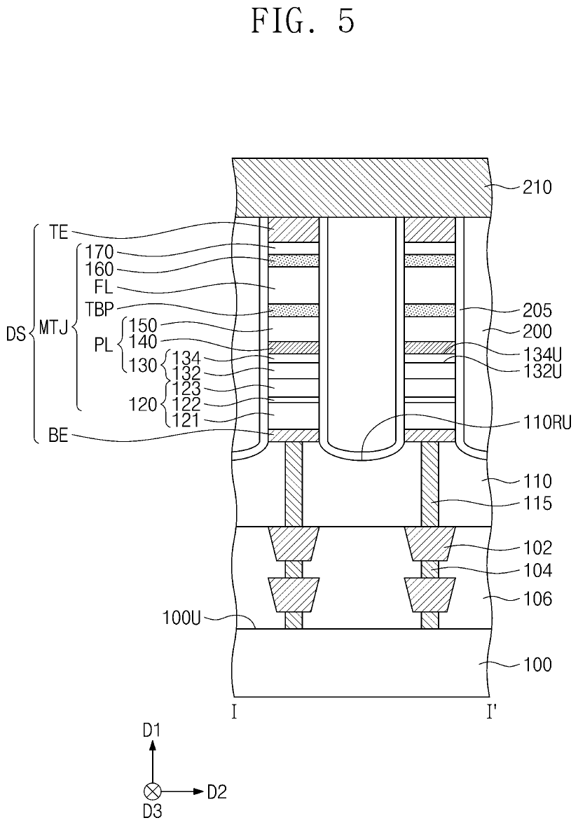

FIG. 4 illustrates a plan view showing a magnetic memory device according to some embodiments of the present inventive concepts. FIG. 5 illustrates a cross-sectional view taken along line I-I′ of FIG. 4. For brevity of description, the following will focus on differences from those discussed above.

Referring to FIGS. 4 and 5, a wiring structure 102 and 104 may be disposed on a substrate 100. The wiring structure 102 and 104 may include lower wiring lines 102 vertically spaced apart from the substrate 100, and may also include lower contacts 104 connected to the lower wiring lines 102. The lower wiring lines 102 may be spaced apart along a first direction D1 from an upper surface 100U of the substrate 100, which first direction D1 is perpendicular to the upper surface 100U of the substrate 100. The lower contacts 104 may be disposed between the substrate 100 and the lower wiring lines 102, and each of the lower wiring lines 102 may be electrically connected to the substrate 100 through a corresponding one of the lower contacts 104. The lower wiring lines 102 and the lower contacts 104 may include, for example, metal (e.g., copper).

The substrate 100 may be provided with selection elements (see SE of FIG. 1) thereon. The selection elements may be, for example, field effect transistors. Each of the lower wiring lines 102 may be electrically connected through a corresponding one of the lower contacts 104 to one terminal (e.g., a drain terminal) of a corresponding one of the selection elements.

A lower interlayer dielectric layer 106 may be disposed on the substrate 100 to cover (at least partially cover) the wiring structure 102 and 104. The lower interlayer dielectric layer 106 may expose upper surfaces of uppermost ones of the lower wiring lines 102. For example, an upper surface of the lower interlayer dielectric layer 106 may be substantially coplanar with those of the uppermost lower wiring lines 102. The lower interlayer dielectric layer 106 may include, for example, silicon oxide, silicon nitride, and/or silicon oxynitride.

A first interlayer dielectric layer 110 may be disposed on the lower interlayer dielectric layer 106. The first interlayer dielectric layer 110 may include, for example, silicon oxide, silicon nitride, and/or silicon oxynitride.

The first interlayer dielectric layer 110 may be provided with data storage patterns DS thereon. The data storage patterns DS may be spaced apart from each other in a second direction D2 and a third direction D3 that intersect each other and are parallel to the upper surface 100U of the substrate 100. The first interlayer dielectric layer 110 may have an upper surface 110RU recessed toward the substrate 100 between the data storage patterns DS.

The first interlayer dielectric layer 110 may be provided therein with lower contact plugs 115 that are spaced apart from each other in the second direction D2 and the third direction D3. The lower contact plugs 115 may be disposed below and electrically connected to corresponding data storage patterns DS. The lower contact plug 115 may extend through (e.g., penetrate) the first interlayer dielectric layer 110 and may be electrically connected to a corresponding one of the uppermost lower wiring lines 102. The lower contact plug 115 may have an upper surface located at a height (or level) higher than that to the recessed upper surface 110RU of the first interlayer dielectric layer 110.

The data storage patterns DS may be correspondingly disposed on and electrically connected to the lower contact plugs 115. Each of the data storage patterns DS may include a lower electrode BE, a magnetic tunnel junction pattern MTJ, and an upper electrode TE that are sequentially stacked on a corresponding one of the lower contact plugs 115. The lower electrode BE may be disposed between the lower contact plug 115 and the magnetic tunnel junction pattern MTJ, and the magnetic tunnel junction pattern MTJ may be disposed between the lower electrode BE and the upper electrode TE. The lower electrode BE, the magnetic tunnel junction pattern MTJ, and the upper electrode TE may be substantially the same as the lower electrode BE, the magnetic tunnel junction pattern MTJ, and the upper electrode TE that are discussed with reference to FIGS. 2 and 3.

The first interlayer dielectric layer 110 may be provided thereon with a second interlayer dielectric layer 200 that is disposed on (e.g., at least partially covers) the data storage patterns DS. The second interlayer dielectric layer 200 may fill (at least partially fill) a space between the data storage patterns DS. A protective dielectric layer 205 may be interposed between the second interlayer dielectric layer 200 and a lateral surface (e.g., a side surface) of each of the data storage patterns DS, and may extend between the second interlayer dielectric layer 200 and the recessed upper surface 110RU of the first interlayer dielectric layer 110. For example, the protective dielectric layer 205 may extend along the recessed upper surface 110RU. The protective dielectric layer 205 may be interposed between the first interlayer dielectric layer 110 and the second interlayer dielectric layer 200. The second interlayer dielectric layer 200 may include, for example, silicon oxide, silicon nitride, and/or silicon oxynitride. For example, the second interlayer dielectric layer 200 may include tetraethylorthosilicate (TEOS) oxide.

An upper wiring line 210 may be disposed on the second interlayer dielectric layer 200. The upper wiring line 210 may extend in the second direction D2. The data storage patterns DS spaced apart from each other in the second direction D2 may be electrically connected to the upper wiring line 210. The upper electrode TE of the data storage pattern DS may be connected (e.g., electrically connected) to a lower surface of the upper wiring line 210, and an upper surface (e.g., an uppermost surface) of the protective dielectric layer 205 may be in contact with the lower surface of the upper wiring line 210. The upper wiring line 210 may be electrically connected through the upper electrode TE to the magnetic tunnel junction pattern MTJ, and may serve as the bit line BL of FIG. 1. The upper wiring line 210 may include a conductive material, such as metal (e.g., copper).

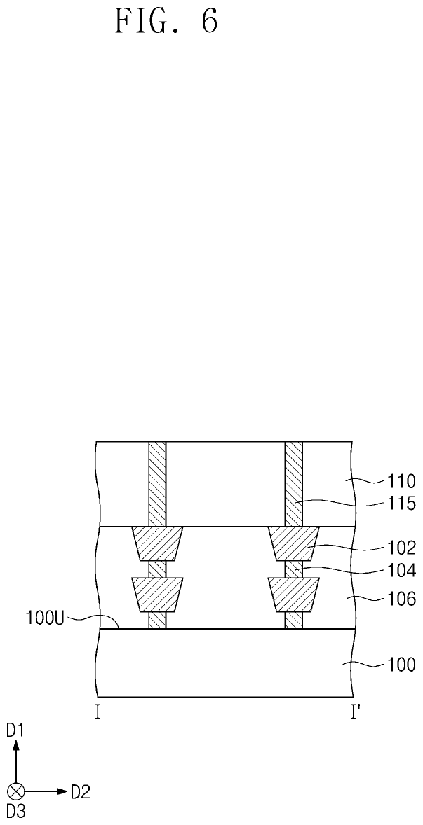

FIGS. 6 to 11 illustrate cross-sectional views taken along line I-I′ of FIG. 4, showing a method of fabricating a magnetic memory device according to some embodiments of the present inventive concepts. A duplicate explanation will be omitted for convenience of description.

Referring to FIG. 6, a substrate 100 may be provided. Selection elements (see SE of FIG. 1) may be formed on the substrate 100, and a wiring structure 102 and 104 may be formed on the selection elements. The wiring structure 102 and 104 may include lower wiring lines 102 and lower contacts 104 connected (e.g., electrically connected) to the lower wiring lines 102.

A lower interlayer dielectric layer 106 may be formed on the substrate 100 to cover (at least partially cover) the lower wiring lines 102. The lower interlayer dielectric layer 106 may expose upper surfaces of uppermost ones of the lower wiring lines 102. A first interlayer dielectric layer 110 may be formed on the lower interlayer dielectric layer 106. Lower contact plugs 115 may be formed to extend through (e.g., penetrate) the first interlayer dielectric layer 110. The lower contact plugs 115 may be correspondingly connected (e.g., electrically connected) to the lower wiring lines 102.

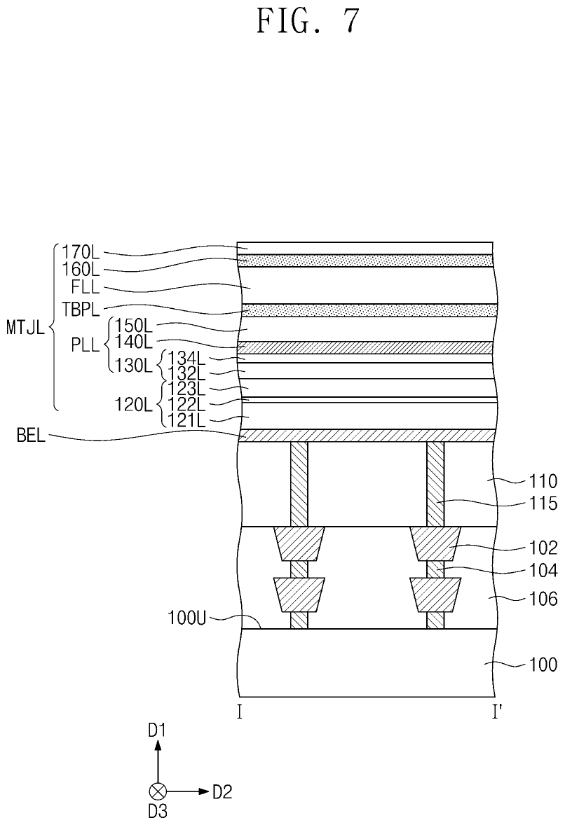

Referring to FIG. 7, a lower electrode layer BEL and a magnetic tunnel junction layer MTJL may be sequentially formed on the first interlayer dielectric layer 110. According to some embodiments, the magnetic tunnel junction layer MTJL may include a seed layer 120L, a reference magnetic layer PLL, a tunnel barrier layer TBPL, a free magnetic layer FLL, an upper non-magnetic layer 160L, and a capping layer 170L that are sequentially stacked on the lower electrode layer BEL. The seed layer 120L may include a first seed layer 121L, a second seed layer 122L, and a third seed layer 123L that are sequentially formed on the lower electrode layer BEL. The reference magnetic layer PLL may include a first pinning layer 130L, an exchange coupling layer 140L, and a second pinning layer 150L. The first pinning layer 130L may include a first magnetic layer 132L and a second magnetic layer 134L that are sequentially formed on the seed layer 120L. The lower electrode layer BEL and the magnetic tunnel junction layer MTJL may be formed by using chemical vapor deposition (CVD), physical vapor deposition (PVD), and/or atomic layer deposition (ALD). For example, a sputtering deposition process may be employed to form the lower electrode layer BEL and the magnetic tunnel junction layer MTJL.

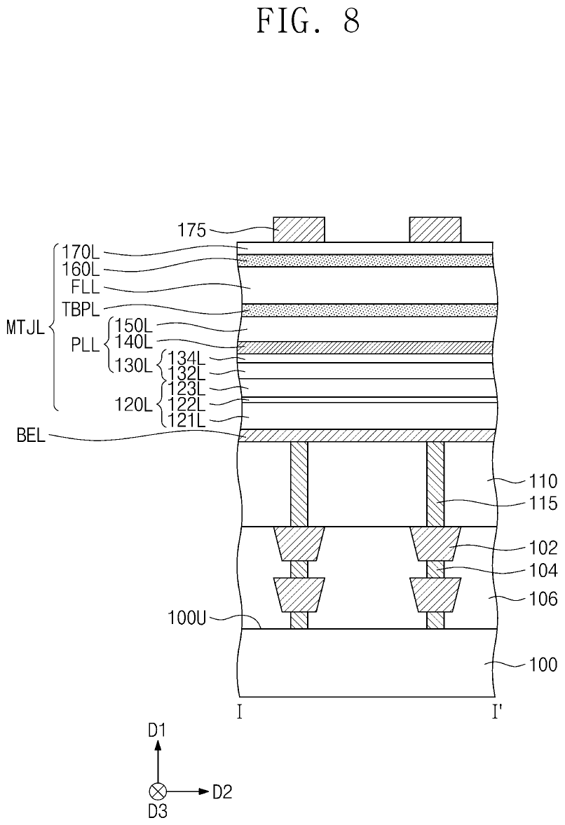

Referring to FIG. 8, a conductive mask pattern 175 may be formed on the magnetic tunnel junction layer MTJL. The conductive mask pattern 175 may define regions where magnetic tunnel junction patterns MTJ will be formed, and may serve as an upper electrode TE of a data storage pattern DS which will be discussed below. The conductive mask patterns 175 may include, for example, at least one selected from metal (e.g., Ta, W, Ru, or Ir) and/or conductive metal nitride (e.g., TiN).

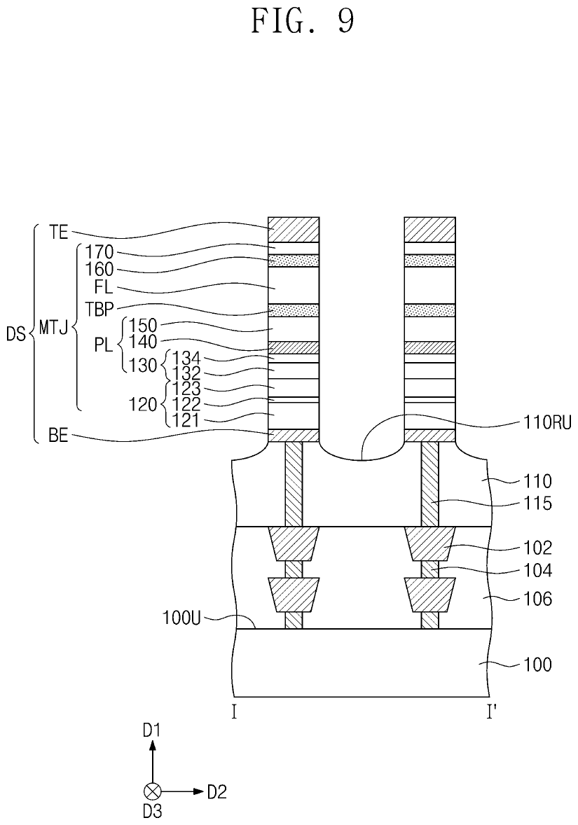

Referring to FIG. 9, a magnetic tunnel junction pattern MTJ and a lower electrode BE may be formed. The formation of the magnetic tunnel junction pattern MTJ and the lower electrode BE may include performing an etching process in which the conductive mask pattern 175 is used as an etching mask to sequentially etch the magnetic tunnel junction layer MTJL and the lower electrode layer BEL. The capping layer 170L, the upper non-magnetic layer 160L, the free magnetic layer FLL, the tunnel barrier layer TBPL, the reference magnetic layer PLL, and the seed layer 120L may be sequentially etched to form a capping pattern 170, an upper non-magnetic pattern 160, a free magnetic pattern FL, a tunnel barrier pattern TBP, a reference magnetic pattern PL, and a seed pattern 120, respectively. An upper electrode TE may be defined to indicate a residue of the conductive mask pattern 175 remaining on the magnetic tunnel junction pattern MTJ after the etching of the magnetic tunnel junction layer MTJL and the lower electrode layer BEL. A data storage pattern DS may be constituted by the upper electrode TE, the capping pattern 170, the upper non-magnetic pattern 160, the free magnetic pattern FL, the tunnel barrier pattern TBP, the reference magnetic pattern PL, the seed pattern 120, and the lower electrode BE.

For example, an ion beam etching process using an ion beam may be employed as the etching process that etches the magnetic tunnel junction layer MTJL and the lower electrode layer BEL. The ion beam may include an inert ion. The etching process may recess an upper portion of the first interlayer dielectric layer 110 between the data storage patterns DS. Therefore, the first interlayer dielectric layer 110 may have an upper surface 110RU that is recessed toward the substrate 100.

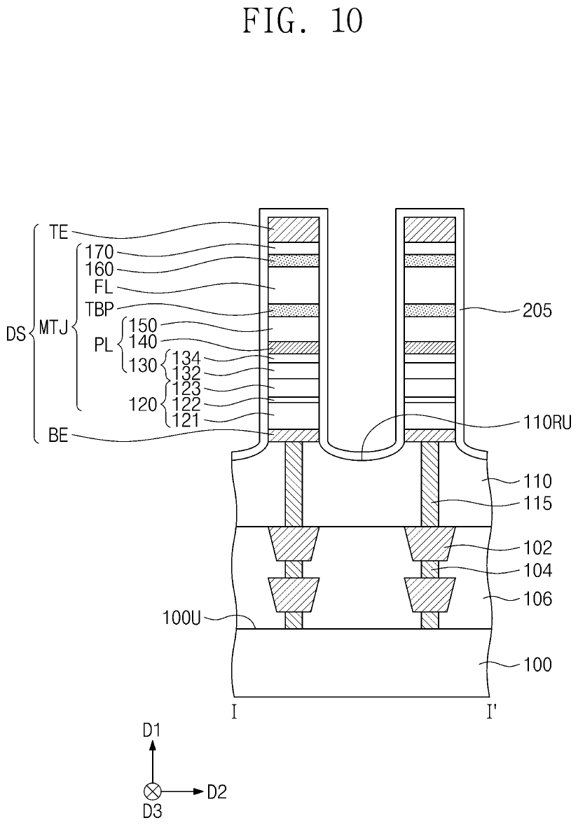

Referring to FIG. 10, a protective dielectric layer 205 may be formed on the first interlayer dielectric layer 110. The protective dielectric layer 205 may extend along the recessed upper surface 110RU of the first interlayer dielectric layer 110, while conformally covering upper and side surfaces of the data storage patterns DS.

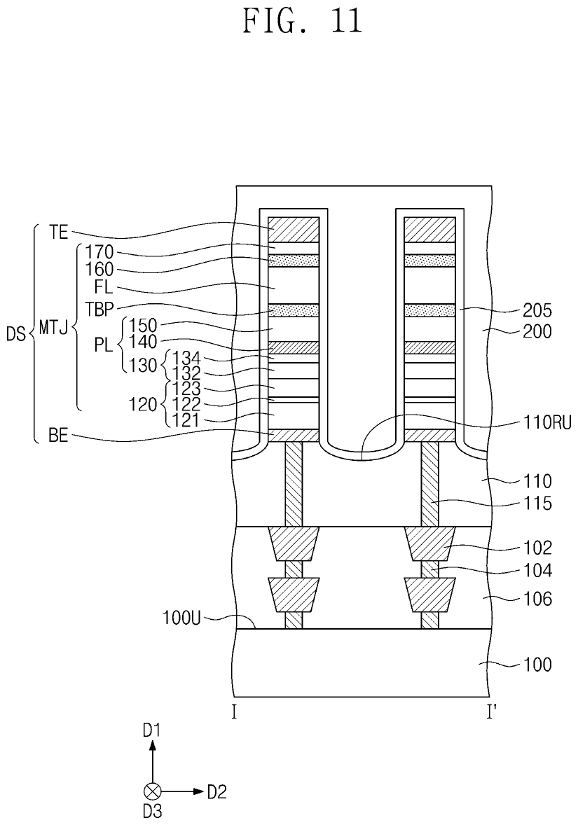

Referring to FIG. 11, a second interlayer dielectric layer 200 may be formed on the protective dielectric layer 205. The second interlayer dielectric layer 200 may cover (at least partially cover) the data storage patterns DS and may fill (at least partially fill) a space between the data storage patterns DS.

Referring back to FIG. 5, the second interlayer dielectric layer 200 and the protective dielectric layer 205 may be partially removed to expose an upper surface of the upper electrode TE. The partial removal of the second interlayer dielectric layer 200 and the protective dielectric layer 205 may include performing a planarization process on the second interlayer dielectric layer 200 and the protective dielectric layer 205 until the upper surface of the upper electrode TE is exposed. The planarization process may include, for example, a chemical mechanical polishing (CMP) process or an etch-back process.

An upper wiring line 210 may be formed on the second interlayer dielectric layer 200. The upper wiring line 210 may be disposed on (e.g., at least partially cover) the exposed upper surface of the upper electrode TE. Therefore, the upper wiring line 210 may be electrically connected to the upper electrode TE.

According to the present inventive concepts, a reference magnetic pattern may simultaneously use bulk-perpendicular magnetic anisotropy (bulk-PMA) and interface-PMA, and may have improved PMA properties. The reference magnetic pattern may thus have a coercive force (Hc) greater than in conventional configuration.

Accordingly, a magnetic memory device may have improved retention properties and increased high-temperature reliability.

Although the present inventive concepts have been described in connection with some embodiments of the present inventive concepts illustrated in the accompanying drawings, it will be understood by one of ordinary skill in the art that variations in form and detail may be made therein without departing from the scope and essential feature of the present inventive concepts. The above disclosed embodiments should thus be considered illustrative and not restrictive.

What is claimed is:

1. A memory device, comprising:
a reference magnetic pattern and a free magnetic pattern that are sequentially stacked on a substrate; and
a tunnel barrier pattern between the reference magnetic pattern and the free magnetic pattern,
wherein the reference magnetic pattern includes:
a first pinning pattern;
a second pinning pattern between the first pinning pattern and the tunnel barrier pattern; and
an exchange coupling pattern between the first pinning pattern and the second pinning pattern, the exchange coupling pattern antiferromagnetically coupling the first pinning pattern and the second pinning pattern to each other,
wherein the first pinning pattern includes:
a first magnetic pattern; and
a second magnetic pattern between the first magnetic pattern and the exchange coupling pattern,
wherein the first magnetic pattern is a single layer including an alloy of a first ferromagnetic element and a first non-magnetic metal element, and
wherein the second magnetic pattern is a single layer including a second ferromagnetic element.

2. The memory device of claim 1, wherein a first thickness in a first direction of the first magnetic pattern is greater than a second thickness in the first direction of the second magnetic pattern, and
wherein the first direction is perpendicular to an upper surface of the substrate.

3. The memory device of claim 2, wherein the first thickness is in a range of 7 Å to 20 Å, and
wherein the second thickness is in a range of 1 Å to 5 Å.

4. The memory device of claim 1, wherein the first ferromagnetic element includes Co, Fe, and/or Ni, and
wherein the first non-magnetic metal element includes Pt and/or Cr.

5. The memory device of claim 4, wherein the first magnetic pattern includes FePt, CoPt, NiPt, and/or CoCrPt.

6. The memory device of claim 1, wherein the second ferromagnetic element includes Co and/or Fe.

7. The memory device of claim 6, wherein the second magnetic pattern includes Co, Fe, and/or CoFe.

8. The memory device of claim 1, wherein the exchange coupling pattern includes Ir and/or Ru.

9. The memory device of claim 1, wherein a thickness in a first direction of the exchange coupling pattern is in a range of 3 Å to 7 Å, and
wherein the first direction is perpendicular to an upper surface of the substrate.

10. The memory device of claim 1, further comprising a seed pattern between the substrate and the reference magnetic pattern,
wherein at least a portion of the seed pattern is amorphous.

11. The memory device of claim 10, wherein the seed pattern includes:
a first seed pattern between the substrate and the first magnetic pattern;
a second seed pattern between the first seed pattern and the first magnetic pattern; and
a third seed pattern between the second seed pattern and the first magnetic pattern,
wherein the first seed pattern is at least partially amorphous.

12. The memory device of claim 11, wherein the first seed pattern includes a metal nitride, and
wherein the first and second seed patterns include a second non-magnetic metal element.

13. The memory device of claim 12, wherein the metal nitride is TaN,
wherein the second non-magnetic metal element is Ta, and
wherein the third seed pattern includes Ru and/or Ir.

14. The memory device of claim 1, wherein the second pinning pattern includes a third ferromagnetic element and further includes Mo, W, and/or B.

15. The memory device of claim 1, wherein the first magnetic pattern includes a hexagonal close-packed (HCP) lattice structure.

16. The memory device of claim 1, wherein
an upper surface of the first magnetic pattern is in direct contact with the second magnetic pattern, and
an upper surface of the second magnetic pattern is in direct contact with the exchange coupling pattern.

17. A memory device, comprising:
a substrate;
a lower interlayer dielectric layer on the substrate;
a lower wiring line in the lower interlayer dielectric layer;
a data storage pattern on the lower wiring line; and
a lower contact plug that extends in a first direction between the lower wiring line and the data storage pattern and electrically connects the lower wiring line and the data storage pattern to each other, wherein the first direction is perpendicular to an upper surface of the substrate,
wherein the data storage pattern includes:
a lower electrode electrically connected to the lower contact plug; and
a seed pattern, a reference magnetic pattern, a tunnel barrier pattern, a free magnetic pattern, and an upper electrode that are sequentially stacked on the lower electrode,
wherein the reference magnetic pattern includes:
a first pinning pattern;
a second pinning pattern between the first pinning pattern and the tunnel barrier pattern; and
an exchange coupling pattern between the first pinning pattern and the second pinning pattern, the exchange coupling pattern antiferromagnetically coupling the first pinning pattern and the second pinning pattern to each other,
wherein the first pinning pattern includes:
a first magnetic pattern; and
a second magnetic pattern between the first magnetic pattern and the exchange coupling pattern,
wherein the first magnetic pattern is a single layer including an alloy of a first ferromagnetic element and a first non-magnetic metal element, and
wherein the second magnetic pattern is a single layer including a second ferromagnetic element.

18. The memory device of claim 17, wherein the first ferromagnetic element includes Co, Fe, and/or Ni,
wherein the first non-magnetic metal element includes Pt and/or Cr,
wherein a first thickness in the first direction of the first magnetic pattern is in a range of 7 Å to 20 Å, and
wherein a second thickness in the first direction of the second magnetic pattern is in a range of 1 Å to 5 Å.

19. The memory device of claim 17, wherein the exchange coupling pattern includes Ir and/or Ru, and
wherein a thickness in the first direction of the exchange coupling pattern is in a range of 3 Å to 7 Å.

20. The memory device of claim 17, wherein the seed pattern includes:
a first seed pattern between the lower electrode and the first magnetic pattern;
a second seed pattern between the first seed pattern and the first magnetic pattern; and
a third seed pattern between the second seed pattern and the first magnetic pattern,
wherein the first seed pattern includes metal nitride,
wherein the first and second seed patterns include a second non-magnetic metal element, and
wherein the first seed pattern is at least partially amorphous.
